(19) United States
(12) Patent Application Publication
(10) Pub. No.: US 2023/0380217 A1
(43) Pub. Date: Nov. 23, 2023

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Kai LU, Wuhan, Hubei (CN)

(21) Appl. No.: 17/789,558

(22) PCT Filed: May 18, 2022
(86) PCT No.: PCT/CN2022/093553

§ 371 Date: Jun. 28, 2022

(51) Int. Cl. H01L 27/32

(52) U.S. Cl. CPC H01L 27/3262; H01L 27/3265; H01L 27/3276; H01L 27/3272

(57) ABSTRACT

A display panel is provided. The display panel includes a shielding metal disposed on at least one of a first active pattern arranged between a first gate and a second gate and a second active pattern arranged between a third gate and a fourth gate, so that the shielding metal can shield a coupling effect of other signals on the first active pattern and the second active pattern, increase a parasitic capacitance of the first active pattern and the second active pattern, reduce a potential change, and improve a problem of display flicker.

### FIELD OF DISCLOSURE

The present disclosure relates to the field of display technologies, and in particular, to a display panel.

### BACKGROUND

Organic light-emitting diode (OLED) display devices are widely used due to their advantages of self-luminescence and flexibility. In existing OLED display devices, a driving circuit based on a low temperature polysilicon (LTPS) technology is used to drive pixels. However, in an actual use process, since a transistor connected to a gate of the driving transistor is a transistor with a dual gate design, a semiconductor pattern between two gate structures is easily coupled by other signals. As a result, a potential is high, and electricity leaks to the driving transistor during a light-emitting stage, resulting in a change in display brightness within one frame, and obvious flickering during low-frequency display.

Therefore, the existing OLED display device has the technical problem that the leakage of the dual gate transistor connected to the gate of the driving transistor causes the display flicker of the OLED display device.

### SUMMARY OF DISCLOSURE

Embodiments of the present disclosure provide a display panel to solve a technical problem of display flickering in an OLED display device due to leakage of a dual gate transistor connected to a gate of a driving transistor in the existing OLED display device.

In order to solve the above problems, technical solutions provided by the present disclosure are as follows:

An embodiment of the present disclosure provides a display panel. The display panel includes a plurality of light-emitting devices arranged in an array and a pixel driving circuit configured to drive one of the light-emitting devices. The pixel driving circuit includes:
a first initialization transistor connected to a first initialization signal line and configured to input a first initialization signal to a first node under a control of a first scan signal;
a switch transistor configured to input a data signal to a second node under a control of a second scan signal;
a driving transistor configured to drive one of the light-emitting devices to emit light under a control of potentials of the first node and the second node; and
a compensation transistor connected to the driving transistor through the first node and the third node, and configured to compensate a threshold voltage of the driving transistor under a control of a third scan signal.

The compensation transistor includes a first gate and a second gate connected to each other, and the first initialization transistor includes a third gate and a fourth gate connected to each other. The display panel further includes a shielding metal, a first active pattern is disposed between the first gate and the second gate, and a second active pattern is disposed between the third gate and the fourth gate. The shielding metal is disposed on at least one of the first active pattern and the second active pattern.

In some embodiments, the shielding metal is disposed on the first active pattern between the first gate and the second gate, or the shielding metal is disposed on the second active pattern between the third gate and the fourth gate.

In some embodiments, the shielding metal is disposed on the first active pattern between the first gate and the second gate.

In some embodiments, the shielding metal is disposed on the second active pattern between the third gate and the fourth gate.

In some embodiments, a first shielding metal is disposed on the first active pattern between the first gate and the second gate, and a second shielding metal is disposed on the second active pattern between the third gate and the fourth gate.

In some embodiments, the display panel further includes a ground terminal. At least one of the first shielding metal and the second shielding metal is connected to the ground terminal.

In some embodiments, the first shielding metal is connected to the ground terminal.

In some embodiments, the second shielding metal is connected to the ground terminal.

In some embodiments, the first shielding metal is connected to the ground terminal, and the second shielding metal is connected to the ground terminal.

In some embodiments, the pixel driving circuit further includes: a second initialization transistor connected to a second initialization signal line and configured to input a second initialization signal to an anode of one of the light-emitting devices under a control of a fourth scan signal;
a first light-emitting control transistor connected to the driving transistor through the second node, and configured to conduct a current of a power high potential signal line to the driving transistor under a control of a light-emitting control signal; and
a second light-emitting control transistor connected to the driving transistor through the third node, and configured to conduct a current flowing from the driving transistor to the anode of one of the light-emitting devices under the control of the light-emitting control signal.

The first shielding metal is connected to one of the first initialization signal line and the second initialization signal line, and the second shielding metal is connected to one of the first initialization signal line and the second initialization signal line.

In some embodiments, the first shielding metal is connected to the second initialization signal line, and the second shielding metal is connected to the first initialization signal line.

In some embodiments, the display panel further includes:
a substrate; and
a pixel driving circuit layer including a plurality of the pixel driving circuits.

The pixel driving circuit includes a semiconductor layer, a first metal layer, a second metal layer, and a third metal layer sequentially disposed on the substrate; the display panel further includes a first interlayer dielectric layer, a second interlayer dielectric layer, and an interlayer insulating layer, the first interlayer dielectric layer is disposed between the semiconductor layer and the first metal layer, the second interlayer dielectric layer is disposed between the first metal layer and the second metal layer, and the interlayer insulating layer is disposed between the second metal layer and the third metal layer; the semiconductor layer includes the first active pattern and the second active pattern, the first metal layer includes the first gate, the second gate, the third gate and the fourth gate, and the shielding metal is disposed on at least one of the second metal layer and the third metal layer.

In some embodiments, the display panel further includes a first via hole extending through the interlayer insulating layer. The second metal layer includes a first portion of the second initialization signal line and the first shielding metal, and the third metal layer includes a second portion of the second initialization signal line.

The first shielding metal is connected to the second portion of the second initialization signal line through the first via hole, and the second portion of the second initialization signal line is connected to the first portion of the second initialization signal line through the first via hole.

In some embodiments, the display panel further includes a second via hole extending through the first interlayer dielectric layer, the second interlayer dielectric layer, and the interlayer insulating layer. The second portion of the second initialization signal line is connected to the second active pattern through the second via hole.

In some embodiments, the display panel further includes a third via hole extending through the interlayer insulating layer The second metal layer includes the second shielding metal, and the third metal layer includes the first initialization signal line.

The first initialization signal line is connected to the second shielding metal through the third via hole.

In some embodiments, the display panel further includes a fourth via hole extending through the interlayer insulating layer, The second metal layer includes a first portion of the second initialization signal line, and the third metal layer includes a second portion of the second initialization signal line and the first shielding metal.

The first shielding metal is connected to the second portion of the second initialization signal line, and the second portion of the second initialization signal line is connected to the first portion of the second initialization signal line through the fourth via hole.

In some embodiments, the third metal layer is formed with a source and a drain.

In some embodiments, the pixel driving circuit further includes a storage capacitor, one end of the storage capacitor is connected to a power high potential signal line, and another end of the storage capacitor is connected to the first node.

In some embodiments, the first initialization transistor is a low temperature polysilicon thin film transistor, the compensation transistor is the 1 low temperature polysilicon thin film transistor, there is a gap between projections of the first gate and the second gate on the first active pattern, and there is a gap between projections of the third gate and the fourth gate on the second active pattern.

In some embodiments, two of the pixel driving circuits which are adjacent to each other are arranged laterally and symmetrically, the first initialization transistors in two of the pixel driving circuits which are adjacent to each other are connected to a same initialization signal line, the compensation transistors in two of the pixel driving circuits which are adjacent to each other are connected to a same scan line.

The present disclosure provides a display panel. The display panel includes a plurality of light-emitting devices arranged in an array and a pixel driving circuit configured to drive one of the light-emitting devices. The pixel driving circuit includes a first initialization transistor, a switch transistor, a driving transistor, and a compensation transistor. The first initialization transistor is connected to a first initialization signal line and is configured to input a first initialization signal to a first node under a control of a first scan signal. The switch transistor is configured to input a data signal to a second node under a control of a second scan signal. The driving transistor is configured to drive one of the light-emitting devices to emit light under a control of potentials of the first node and the second node. The compensation transistor is connected to the driving transistor through the first node and the third node, and is configured to compensate a threshold voltage of the driving transistor under a control of a third scan signal. The compensation transistor includes a first gate and a second gate connected to each other, and the first initialization transistor includes a third gate and a fourth gate connected to each other. The display panel further includes a shielding metal, a first active pattern is disposed between the first gate and the second gate, and a second active pattern is disposed between the third gate and the fourth gate. The shielding metal is disposed on at least one of the first active pattern and the second active pattern. In the present disclosure, by disposing the shielding metal on at least one of the first active pattern arranged between the first gate and the second gate and the second active pattern arranged between the third gate and the fourth gate, so that the shielding metal can shield a coupling effect of other signals on the first active pattern and the second active pattern, and increase a parasitic capacitance of the first active pattern and the second active pattern. Therefore, even if the first active pattern and the second active pattern are coupled, a potential change can be reduced, thereby reducing leakage to a gate of the driving transistor and improving a problem of display flicker.

### BRIEF DESCRIPTION OF DRAWINGS

FIG. 1 is a circuit diagram of a display panel of an embodiment of the present disclosure.

FIG. 2 is a first perspective view of a display panel of an embodiment of the present disclosure.

FIG. 3 is a cross-sectional view of the perspective view in FIG. 2.

FIG. 4 is an exploded view of a semiconductor layer of the display panel in FIG. 2.

FIG. 5 is an exploded view of a first metal layer of the display panel in FIG. 2.

FIG. 6 is an exploded view of a second metal layer of the display panel in FIG. 2.

FIG. 7 is an exploded view of a third metal layer of the display panel in FIG. 2.

FIG. 8 is a second perspective view of a display panel of an embodiment of the present disclosure.

FIG. 9 is a third perspective view of a display panel of an embodiment of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only some, but not all, embodiments of the present disclosure. Based on the embodiments in the present disclosure, all other embodiments obtained by those skilled in the art without creative efforts shall fall within the protection scope of the present disclosure.

The embodiments of the present disclosure provide a display panel and a display device to solve a technical problem that an OLED display device has display flicker due to leakage of a dual gate transistor connected to a gate of a driving transistor in the existing OLED display device.

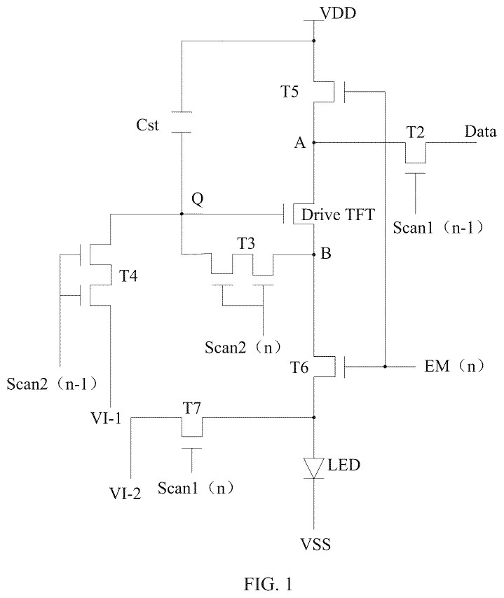

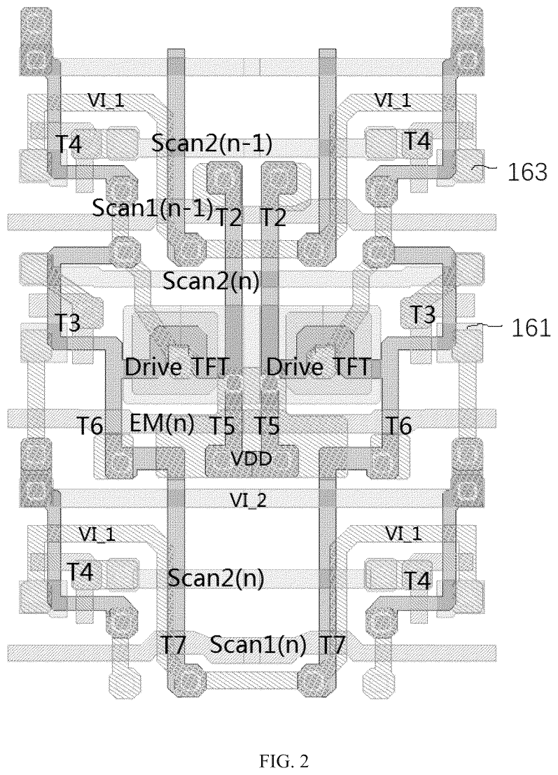

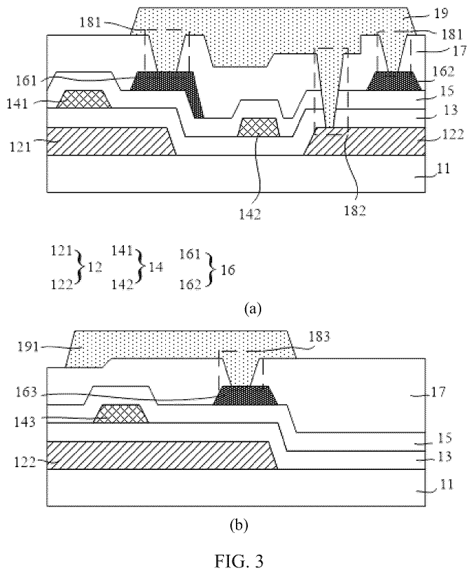

As shown in FIG. 1, FIG. 2, and FIG. 3, an embodiment of the present disclosure provides a display panel. The display panel includes a plurality of light-emitting devices LED arranged in an array and a pixel driving circuit for driving one of the light-emitting devices LED. The pixel driving circuit includes a first initialization transistor T4, a switch transistor T2, a driving transistor Drive TFT, and a compensation transistor T3.

The first initialization transistor T4 is connected to a first initialization signal line and is configured to input a first initialization signal to a first node Q under a control of a first scan signal.

The switch transistor T2 is configured to input a data signal to a second node A under a control of a second scan signal.

The driving transistor Drive TFT is configured to drive one of the light-emitting devices LED to emit light under a control of potentials of the first node Q and the second node A.

The compensation transistor T3 is connected to the driving transistor Drive TFT through the first node Q and the second node A, and is configured to compensate a threshold voltage of the driving transistor Drive TFT under a control of a third scan signal.

The compensation transistor T3 includes a first gate and a second gate connected to each other. The first initialization transistor T4 includes a third gate and a fourth gate connected to each other. The display panel further includes a shielding metal (e.g., a first shielding metal 161 in FIG. 2). The shielding metal is disposed on at least one of a first active pattern 121 arranged between the first gate and the second gate and a second active pattern 122 arranged between the third gate and the fourth gate (for example, the first shielding metal 161 is disposed on the first active pattern 121 in FIG. 3).

The embodiment of the present disclosure provide the display panel. In the display panel, by disposing the shielding metal on at least one of the first active pattern arranged between the first gate and the second gate and the second active pattern arranged between the third gate and the fourth gate, so that the shielding metal can shield a coupling effect of other signals on the first active pattern and the second active pattern, and increase a parasitic capacitance of the first active pattern and the second active pattern. Therefore, even if the first active pattern and the second active pattern are coupled, a potential change can be reduced, thereby reducing leakage to a gate of the driving transistor and improving a problem of display flicker.

It should be noted that, as can be seen from both FIG. 1 and FIG. 2, two gates of the compensation transistor T3 will be connected. Therefore, in FIG. 1 and FIG. 2, the first gate and the second gate are actually two portions of one gate. Taking FIG. 2 as an example, the first gate and the second gate are two portions of the gate that are perpendicular to each other. Therefore, the first gate and the second gate are not specifically marked. Similarly, the third gate and fourth gate of the first initialization transistor T4 are also two portions of the gate that are perpendicular to each other.

It should be noted that, as can be seen from a circuit diagram in FIG. 1 and a perspective view in FIG. 2, in the semiconductor layer, the active pattern includes two portions that overlap with a projection of the gate of the transistor and another portion located between the overlapping portions. As shown in FIG. 2, it can be seen that the first active pattern and a projection of the gate of compensation transistor T3 have a portion where the projection overlaps. Then it can be known that the first active pattern arranged between the first gate and the second gate refers to another portion arranged between the two portions where the first active pattern overlaps with the projection of the gate of compensation transistor T3. Similarly, the second active pattern arranged between the third gate and the fourth gate refers to another portion arranged between the two portions where the second active pattern overlaps with the projection of the gate of the first initialization transistor T4.

In one embodiment, the shielding metal is disposed on the first active pattern arranged between the first gate and the second gate, or the shielding metal is disposed on the second active pattern arranged between the third gate and the fourth gate metal.

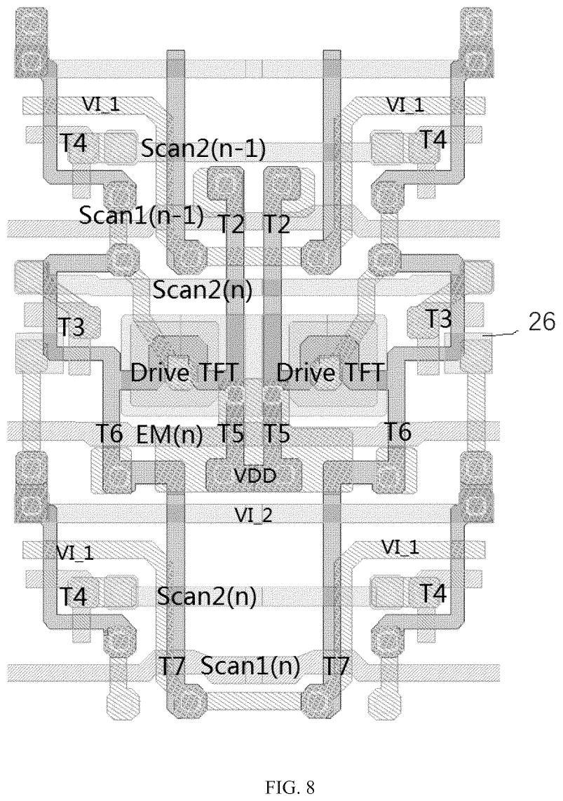

Specifically, as shown in FIG. 8, a shielding metal 26 is disposed on the first active pattern between the first gate and the second gate. By setting the shielding metal on the first active pattern between the first gate and the second gate, the shielding metal can shield the coupling effect of other signals on the first active pattern, and also increase the parasitic capacitance of the first active pattern. Even if the coupling effect of other signals on the first active pattern occurs, the potential change can be reduced, the leakage of the compensation transistor to the gate of the driving transistor can be reduced, the display brightness change within a frame can be reduced, and the problem of low frequency display flicker can be improved.

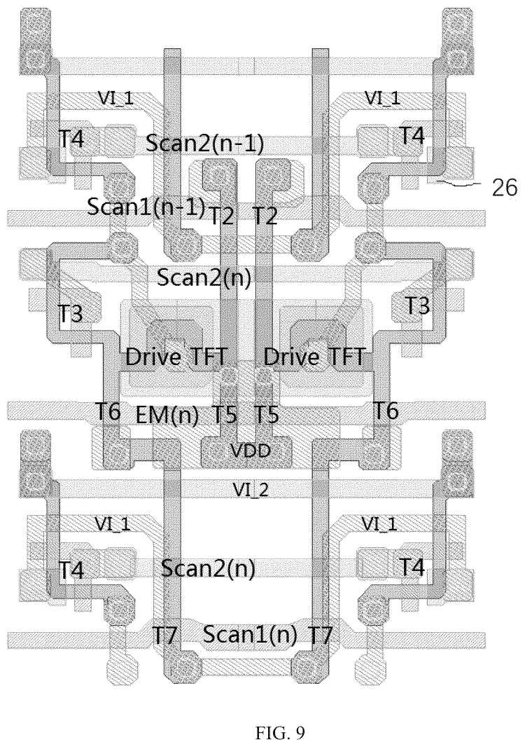

Specifically, as shown in FIG. 9, a shielding metal 26 is disposed on the second active pattern between the third gate and the fourth gate. By setting the shielding metal on the second active pattern between the third gate and the fourth gate, the shielding metal can shield the coupling effect of other signals on the second active pattern, and also increase the parasitic capacitance of the second active pattern. Even if the coupling effect of other signals on the second active pattern occurs, the potential change can be reduced, the leakage of the first initialization transistor to the gate of the driving transistor can be reduced, the display brightness change within a frame can be reduced, and the problem of low frequency display flicker can be improved.

For both the compensation transistor and the first initialization transistor, the leakage of the driving transistor will cause the display to flicker. In an embodiment, as shown in FIG. 2 and FIG. 3, a first shielding metal 161 is disposed on the first active pattern 121 between the first gate and the second gate. A second shielding metal 163 is disposed on the second active pattern 122 between the third gate and the fourth gate. The first shielding metal is disposed on the first active pattern arranged between the first gate and the second gate, and the second shielding metal is disposed on the second active pattern arranged between the third gate and the fourth gate. The first shielding metal shields the first active pattern to reduce the leakage of the compensation transistor. The second shielding metal shields the second active pattern to reduce the leakage of the first initialization transistor. It reduces display brightness change within a frame and improves low frequency display flickering.

The potential change for shielding metal will cause the problem of poor shielding effect. In one embodiment, the display panel further includes a ground terminal. At least one of the first shielding metal and the second shielding metal is connected to the ground terminal.

Specifically, the first shielding metal is connected to the ground terminal. Alternatively, the second shielding metal is connected to the ground terminal. Alternatively, the first shielding metal is connected to the ground terminal, and the second shielding metal is connected to the ground terminal. The potentials of the first shielding metal and the second shielding metal are kept stable by connecting the first shielding metal and the second shielding metal to the ground terminal. Then, the potential of the first active pattern of the compensation transistor can be stabilized by the first shielding metal, so as to prevent the potential at this place from being coupled too high or too low by other signals, thereby reducing a voltage difference between a source and a drain of the driving transistor, reducing a small leakage current. The potential of the second active pattern of the first initialization transistor is stabilized by the second shielding metal, so as to prevent the potential at this place from being coupled too high or too low by other signals, thereby reducing a voltage difference between a source and a drain of the driving transistor and reducing leakage current. By reducing the leakage current of the driving transistor and the first initialization transistor, the brightness change of the display panel in one frame is reduced, and the display flicker is improved.

In an embodiment, as shown in FIG. 1, FIG. 2, and FIG. 3, the pixel driving circuit further includes a second initialization transistor T7, a first light-emitting control transistor T5, and a second light-emitting control transistor T6. The second initialization transistor T7 is connected to a second initialization signal line VI-2, and is configured to input a second initialization signal to an anode of the light-emitting device LED under a control of a fourth scan signal.

The first light-emitting control transistor T5 is connected to the driving transistor Drive TFT through the second node A, and is configured to conduct a current of a power high potential signal line VDD to the driving transistor Drive TFT under a control of a light-emitting control signal.

The second light-emitting control transistor T6 is connected to the driving transistor Drive TFT through the third node B, and is configured to conduct a current flowing from the driving transistor Drive TFT to the anode of the light-emitting device LED under the control of the light-emitting control signal.

The first shielding metal 161 is connected to one of the first initialization signal line 191 and the second initialization signal line. The second shielding metal is connected to one of the first initialization signal line 191 and the second initialization signal line. The second shielding metal is connected to one of the first initialization signal line and the second initialization signal line by connecting the first shielding metal to one of the first initialization signal line and the second initialization signal line. Since the potentials of the first initialization signal line and the second initialization signal line are stable, the potentials of the first shielding metal and the second shielding metal can be stabilized. Furthermore, the potentials of the first active pattern of the compensation transistor and the second active pattern of the first initialization transistor are stabilized, and the leakage current of the compensation transistor and the first initialization transistor is reduced or eliminated. It reduces the display brightness change within a frame, improves the problem of display flickering.

It should be noted that, in the circuit diagram shown in FIG. 1, the first initialization signal line is indicated by VI-1. In the cross-sectional view shown in FIG. 3, the first initialization signal line is indicated by reference numeral 191. This is just a different way of marking in different diagrams. In fact, the first initialization signal line in the circuit diagram shown in FIG. 1 corresponds to the first initialization signal line in the cross-sectional diagram shown in FIG. 3. Similarly, the component in other circuit diagrams and cross-sectional diagrams with different reference numerals are also the same component, which will not be repeated here.

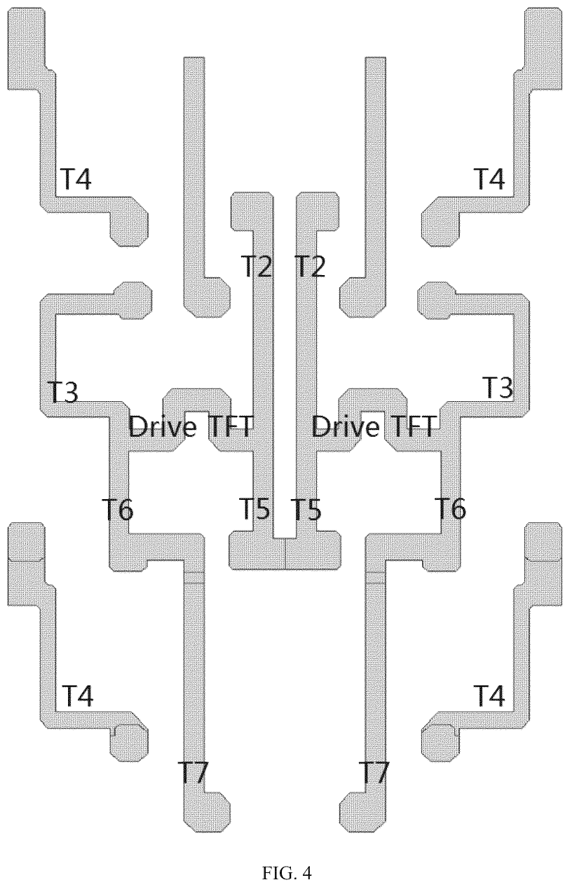

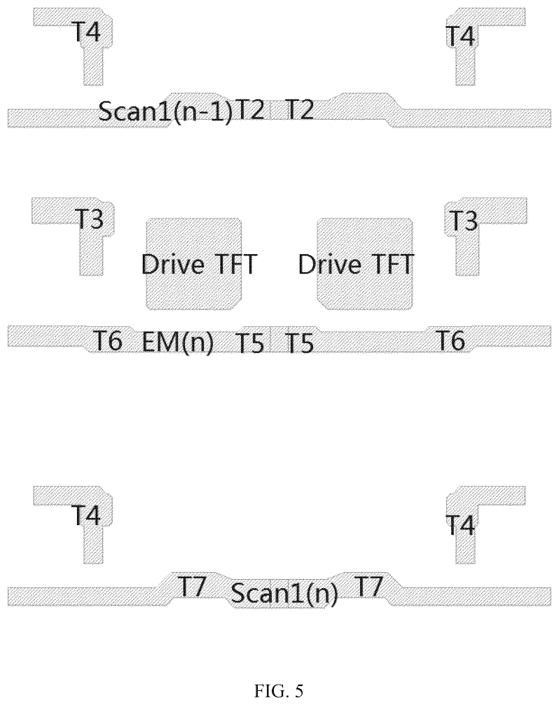

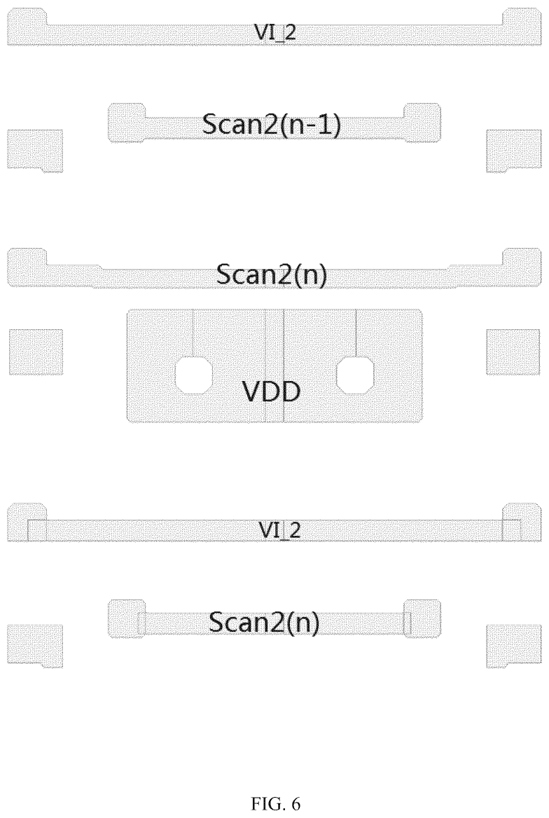

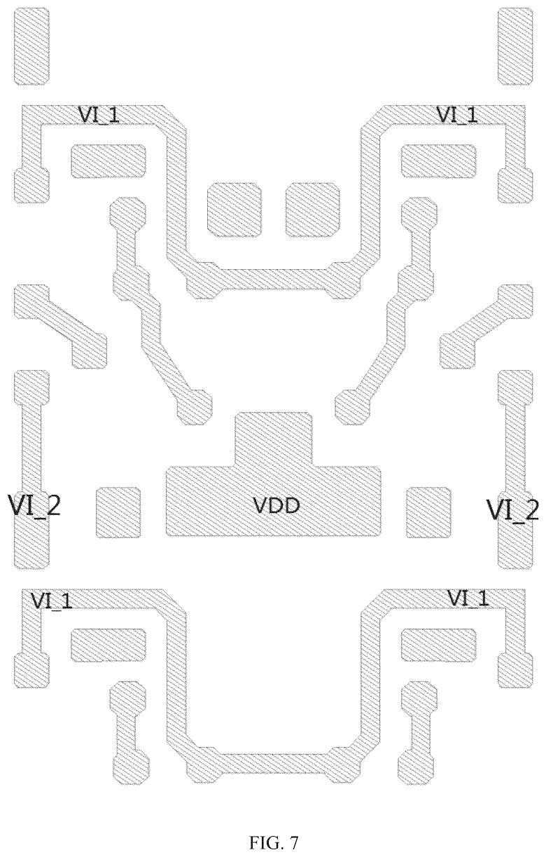

As shown in FIG. 4 to FIG. 7, FIG. 4 is a perspective view of a semiconductor layer in FIG. 3, FIG. 5 is a perspective view of a first metal layer in FIG. 3, FIG. 6 is a perspective view of a second metal layer in FIG. 3, and FIG. 7 is a perspective view of a third metal layer in FIG. 3.

A distance between a line connecting the first shielding metal and the second shielding metal will lead to a complicated layer structure and layer connection structure. In an embodiment, as shown in FIG. 2 to FIG. 7, the first shielding metal 161 is connected to the second initialization signal line VI-2, and the second shielding metal 163 is connected to the first initialization signal line VI-1. In a single sub-pixel, since the compensation transistor is close to the second initialization signal line, and the first initialization transistor is close to the first initialization signal line, the first shielding metal is connected to the second initialization signal line, and the first initialization transistor is connected to the first initialization signal line. Thus, a length of the line connected to the first shielding metal can be shortened, and the complexity of the film layer structure and the film layer connection structure can be reduced.

In one embodiment, the display panel includes:
a substrate; and
a pixel driving circuit layer including a plurality of pixel driving circuits.

The pixel driving circuit includes a semiconductor layer, a first metal layer, a second metal layer, and a third metal layer sequentially disposed on the substrate. The semiconductor layer includes the first active pattern and the second active pattern, the first metal layer includes the first gate, the second gate, the third gate and the fourth gate. The display panel further includes a shielding metal layer. The shielding metal layer is formed with the shielding metal. By setting the shielding metal layer, the shielding metal layer forms the shielding metal, it is possible to prevent the shielding metal from affecting the structural design of other film layers.

For a technical problem that setting of the shielding metal layer will lead to a larger thickness of the display panel, in an embodiment, as shown in FIG. 3, the display panel includes:
a substrate 11; and
a pixel driving circuit layer including a plurality of pixel driving circuits.

The pixel driving circuit includes a semiconductor layer 12, a first metal layer 14, a second metal layer 16, and a third metal layer 19 stacked on the substrate 11 in sequence. The display panel further includes a first interlayer insulating layer 13, a second interlayer insulating layer 15, and an interlayer dielectric layer 17. The first interlayer dielectric layer 13 is disposed between the semiconductor layer 12 and the first metal layer 14. The second interlayer dielectric layer 15 is disposed between the first metal layer 14 and the second metal layer 16. The interlayer insulating layer 17 is disposed between the second metal layer 16 and the third metal layer 19. The semiconductor layer 12 includes the first active pattern 121 and the second active pattern 122. The first metal layer 14 includes the first gate, the second gate, the third gate, and the fourth gate. At least one of the second metal layer 16 and the third metal layer 19 is provided with the shielding metal. By arranging the shielding metal on the second metal layer and the third metal layer, there is no need to additionally arrange the shielding metal layer, thereby reducing the thickness of the display panel.

A distance between the shielding metal and the semiconductor layer is far away, which will lead to a problem of poor shielding effect. In an embodiment, as shown in FIG. 2, FIG. 3 (a) and FIG. 4 to FIG. 7, the display panel is provided with a first via hole 181 extending through the interlayer insulating layer 17. The second metal layer 16 includes a first portion 162 of the second initialization signal line VI-2 and the first shielding metal 161. The third metal layer 19 includes a second portion of the second initialization signal line VI-2.

The first shielding metal 161 is connected to the second portion of the second initialization signal line VI-2 through the first via hole 181. The second portion of the second initialization signal line VI-2 is connected to the first portion 181 of the second initialization signal line VI-2 through the first via hole 181. By arranging the first shielding metal on the second metal layer, the distance between the first shielding metal and the first active pattern of the compensation transistor is made closer. The resulting capacitance is larger, the first shielding metal has a better shielding effect on the first active pattern, the leakage of the compensation transistor is reduced, and the flicker of the display panel is improved.

It should be noted that FIG. 3 (a) is a cross-sectional view of the compensation transistor and the second initialization signal line in FIG. 2. Therefore, a source and a drain of the compensation transistor are not shown in FIG. 3 (a). Moreover, for the first gate and the second gate of the compensation transistor, only a portion of the first gate and the second gate can be indicated by a reference numeral 141 due to the use of the cross-sectional view, and the light-emitting control signal line EM(n) can be indicated by a reference numeral 142. Similarly, FIG. 3 (b) shows only a portion of the third gate and the fourth gate with a reference numeral 143. Moreover, FIG. 3 (a) shows only a portion of the third metal layer 19. This portion is a connection portion between the first shielding metal and the first portion of the second initialization signal line. Therefore, this portion can be used as the second portion of the second initialization signal line.

For the problem that a high potential of the first initialization transistor will affect a gate potential of the driving transistor, in one embodiment, as shown in FIG. 2, FIG. 3 (a) and FIG. 4 to FIG. 7, the display panel is provided with a second via hole 182 extending through the first interlayer dielectric layer 13, the second interlayer dielectric layer 15, and the interlayer insulating layer 17. The second portion of the second initialization signal line VI-2 is connected to the second active pattern 122 through the second via hole 182. By connecting the second portion of the second initialization signal line with the second active pattern, the second initialization signal line can reset the gate of the first initialization transistor. It prevents the high gate potential of the first initialization transistor from keeping the first initialization transistor turned on, which in turn affects the gate potential of the driving transistor.

The distance between the shielding metal and the semiconductor layer is far away, which will lead to the problem of poor shielding effect. In an embodiment, as shown in FIG. 2, FIG. 3 (b) and FIG. 4 to FIG. 7, the display panel is provided with a third via hole 183 extending through the interlayer insulating layer 17. The second metal layer includes the second shielding metal 163. The third metal layer includes the first initialization signal line 191.

The first initialization signal line 191 is connected to the second shielding metal 163 through the third via hole 183. By arranging the second shielding metal on the second metal layer, a distance between the second shielding metal and the second active pattern of the first initialization transistor is closer, so that the formed capacitance is larger. The second shielding metal has a better shielding effect on the second active pattern, which reduces the leakage of the first initialization transistor and improves the flicker of the display panel.

In an embodiment, the display panel is provided with a fourth via hole extending through the interlayer insulating layer. The second metal layer includes the first portion of the second initialization signal line. The third metal layer includes the second portion of the second initialization signal line and the first shielding metal.

The first shielding metal is connected to the second portion of the second initialization signal line. The second portion of the second initialization signal line is connected to the first portion of the second initialization signal line through the fourth via hole. The first shielding metal is formed by the third metal layer, and the first shielding metal can be directly connected to the second initialization signal line without forming a via hole and without occupying a space of the second metal layer, thereby reducing the difficulty of the process.

In one embodiment, the first initialization transistor is a low temperature polysilicon thin film transistor. The compensation transistor is a low temperature polysilicon thin film transistor. There is a gap between projections of the first gate and the second gate on the first active pattern. There is a gap between projections of the third gate and the fourth gate on the second active pattern. The present disclosure will use a dual gate design for the low temperature polysilicon thin film transistors. The semiconductor pattern between the two gates is easily coupled by other signals, resulting in a high potential and leakage to the driving transistor during a light-emitting stage. By setting the shielding metal, the leakage to the gate of the driving transistor is reduced, and the display flicker is improved.

In one embodiment, two adjacent pixel driving circuits are arranged laterally and symmetrically. The first initialization transistors in two adjacent pixel driving circuits are connected to a same initialization signal line. The compensation transistors in two adjacent pixel driving circuits are connected to a same scan line. By connecting the first initialization transistors in the two adjacent pixel driving circuits to the same initialization signal line, the compensation transistors in the two adjacent pixel driving circuits are connected to the same scan line, thereby reducing an occupied space of sub-pixels, and improving an aperture of the display panel. Since there is no need to disconnect a part of the wiring between two sub-pixels, the difficulty of the process is reduced, and a yield of the display panel is improved.

Specifically, it can be seen from FIG. 2 to FIG. 7 that the pixel driving circuits arranged laterally are arranged symmetrically. A portion of electrodes and metal traces in the two pixel driving circuits are shared, which reduces a space occupied by a single sub-pixel and reduces the process difficulty of the display panel.

In one embodiment, the first metal layer is formed with a gate, the second metal layer is formed with a plate of a capacitor, and the third metal layer is formed with a source and a drain.

In an embodiment, as shown in FIG. 1, the pixel driving circuit further includes a storage capacitor Cst. One end of the storage capacitor Cst is connected to the power high potential signal line VDD. The other end of the storage capacitor Cst is connected to the first node Q.

It can be understood that, in the embodiment of the present disclosure, as shown in FIG. 1, the data line Data transmits the data signal, the first initialization signal line VI-1 transmits the first initialization signal, the second initialization signal line VI-2 transmits the second initialization signal, a first scan signal line Scan2(n−1) transmits the first scan signal, a second scan signal line Scan1(n−1) transmits the second scan signal, and a third scan signal line Scan2(n) transmits the third scan signal, a fourth scan signal line Scan1(n) transmits the fourth scan signal, the light-emitting control signal line EM(n) transmits the light-emitting control signal, and a power low potential signal line VSS transmits a low potential.

It should be noted that Scan1 and Scan2 represent two sets of scan lines, and Scan(n−1) and Scan(n) represent two-stage scan lines.

It should be noted that, in FIG. 2, an arrangement and a connection relationship of each element are shown by the pixel driving circuit in the two sub-pixels. To illustrate how the repeating units are set up, each sub-pixel shows the first initialization transistor of a next stage. Therefore, in FIG. 2 there will be four T4. In fact, each sub-pixel in FIG. 2 includes only one first initialization transistor. FIG. 4 to FIG. 7 are exploded views of FIG. 2, and thus are also shown with two sub-pixels, and partially show the structure of the next stage.

Specifically, FIG. 4 is a design of the active pattern of each transistor, and FIG. 5 is a design of the gate of each transistor and the wiring of the first metal layer, FIG. 6 is a design of the wiring of the second metal layer, and FIG. 7 is a design of the source/drain and the wiring of the third metal layer.

Specifically, as shown in FIG. 4, Drive TFT, T2, T3, T4, T5, T6, and T7 respectively represent the setting positions of the active patterns of the transistors, and it can be seen that the first active pattern and the second active pattern have a bent structure. As shown in FIG. 5, the gates of the transistors are represented by Drive TFT, T2, T3, T4, T5, T6, and T7, respectively. It can be seen from FIG. 5 that the first gate and the second gate of the compensation transistor T3 are two parts that are perpendicular to each other. The third gate and the fourth gate of the first initialization transistor T4 are two parts that are perpendicular to each other. As shown in FIG. 6 and FIG. 7, the structure and arrangement position of each wiring are shown. It can be seen from FIG. 6 and FIG. 7 that the second initialization signal line VI-2 includes a first portion at the second metal layer and a second portion at the third metal layer. Also, it can be seen from FIG. 6 and FIG. 7, in FIG. 2, elements arranged in different film layers can be connected through via holes and through the metal of the corresponding film layers. Therefore, there are unlabeled parts in FIG. 6 and FIG. 7. The unlabeled part indicates that there is a via hole connection here, and this wiring can be used as a connection trace.

It should be noted that, in the above embodiment, the arrangement of the shielding metal is described in detail with the pixel driving circuit shown in FIG. 1 and the perspective view shown in FIG. 2. However, embodiments of the present disclosure are not limited thereto. For example, the pixel driving circuit adopts other design methods, for example, there are other transistors with the dual gate design connected to the driving transistor. It is also possible to shield the active pattern of other transistors with the dual gate design. Alternatively, when the display panel also includes other metal layers (for example, when a source-drain layer and a transition metal layer disposed on the source-drain layer are included, the transition metal layer can be used to form the shielding metal), the above design method can also be used to set the shielding metal, so that the shielding metal can shield the first active pattern and the second active pattern, reduce the leakage current to the driving transistor, and improve the display flicker.

It should be noted that, the display panel shown in FIG. 8 and FIG. 9 differs from the display panel shown in FIG. 2 only in the arrangement position of the shielding metal and the connection position of the shielding metal. The exploded views of the display panel shown in FIG. 8 and FIG. 9 can be determined similarly to the exploded view of the display panel in FIG. 2, and details are not described herein again.

Moreover, an embodiment of the present disclosure provides a display device. The display device includes the display panel described in any of the above embodiments and electronic components.

According to the above embodiments, it can be known that:

The embodiments of the present disclosure provide the display panel and the display device. The display panel includes the plurality of light-emitting devices arranged in the array and the pixel driving circuit configured to drive one of the light-emitting devices. The pixel driving circuit includes the first initialization transistor, the switch transistor, the driving transistor, and the compensation transistor. The first initialization transistor is connected to the first initialization signal line and is configured to input the first initialization signal to the first node under the control of the first scan signal. The switch transistor is configured to input the data signal to the second node under the control of the second scan signal. The driving transistor is configured to drive one of the light-emitting devices to emit light under the control of potentials of the first node and the second node. The compensation transistor is connected to the driving transistor through the first node and the third node, and is configured to compensate the threshold voltage of the driving transistor under the control of the third scan signal. The compensation transistor includes the first gate and the second gate connected to each other, and the first initialization transistor includes the third gate and the fourth gate connected to each other. The display panel further includes the shielding metal, the first active pattern is disposed between the first gate and the second gate, and the second active pattern is disposed between the third gate and the fourth gate. The shielding metal is disposed on at least one of the first active pattern and the second active pattern. In the present disclosure, by disposing the shielding metal on at least one of the first active pattern arranged between the first gate and the second gate and the second active pattern arranged between the third gate and the fourth gate, so that the shielding metal can shield the coupling effect of other signals on the first active pattern and the second active pattern, and increase the parasitic capacitance of the first active pattern and the second active pattern. Therefore, even if the first active pattern and the second active pattern are coupled, the potential change can be reduced, thereby reducing leakage to the gate of the driving transistor and improving the problem of display flicker.

In the above-mentioned embodiments, the description of each embodiment has its own emphasis. For parts that are not described in detail in a certain embodiment, reference may be made to the relevant descriptions of other embodiments.

The display panel and the display device provided by the embodiments of the present disclosure are described above in detail. The principles and implementations of the present disclosure are explained with specific examples in this specification. The descriptions of the above embodiments are only used to help understand the technical solutions and core ideas of the present disclosure. Those of ordinary skill in the art should understand that they can still make modifications to the technical solutions described in the foregoing embodiments, or perform equivalent replacements to some of the technical features. These modifications or replacements do not make the essence of the corresponding technical solutions deviate from the scope of the technical solutions of the various embodiments of the present disclosure.

What is claimed is:

1. A display panel, comprising a plurality of light-emitting devices arranged in an array and a pixel driving circuit configured to drive one of the light-emitting devices, wherein the pixel driving circuit comprises:
a first initialization transistor connected to a first initialization signal line and configured to input a first initialization signal to a first node under a control of a first scan signal;
a switch transistor configured to input a data signal to a second node under a control of a second scan signal;
a driving transistor configured to drive one of the light-emitting devices to emit light under a control of potentials of the first node and the second node; and
a compensation transistor connected to the driving transistor through the first node and the third node, and configured to compensate a threshold voltage of the driving transistor under a control of a third scan signal;
wherein the compensation transistor comprises a first gate and a second gate connected to each other, and the first initialization transistor comprises a third gate and a fourth gate connected to each other; wherein the display panel further comprises a shielding metal, a first active pattern is disposed between the first gate and the second gate, and a second active pattern is disposed between the third gate and the fourth gate; and the shielding metal is disposed on at least one of the first active pattern and the second active pattern.

2. The display panel according to claim 1, wherein the shielding metal is disposed on the first active pattern between the first gate and the second gate, or the shielding metal is disposed on the second active pattern between the third gate and the fourth gate.

3. The display panel according to claim 2, wherein the shielding metal is disposed on the first active pattern between the first gate and the second gate.

4. The display panel according to claim 2, wherein the shielding metal is disposed on the second active pattern between the third gate and the fourth gate.

5. The display panel according to claim 1, wherein a first shielding metal is disposed on the first active pattern between the first gate and the second gate, and a second shielding metal is disposed on the second active pattern between the third gate and the fourth gate.

6. The display panel according to claim 5, further comprising a ground terminal, wherein at least one of the first shielding metal and the second shielding metal is connected to the ground terminal.

7. The display panel according to claim 6, wherein the first shielding metal is connected to the ground terminal.

8. The display panel according to claim 6, wherein the second shielding metal is connected to the ground terminal.

9. The display panel according to claim 6, wherein the first shielding metal is connected to the ground terminal, and the second shielding metal is connected to the ground terminal.

10. The display panel according to claim 5, wherein the pixel driving circuit further comprises:
a second initialization transistor connected to a second initialization signal line and configured to input a second initialization signal to an anode of one of the light-emitting devices under a control of a fourth scan signal;
a first light-emitting control transistor connected to the driving transistor through the second node, and configured to conduct a current of a power high potential signal line to the driving transistor under a control of a light-emitting control signal; and
a second light-emitting control transistor connected to the driving transistor through the third node, and configured to conduct a current flowing from the driving transistor to the anode of one of the light-emitting devices under the control of the light-emitting control signal;
wherein the first shielding metal is connected to one of the first initialization signal line and the second initialization signal line, and the second shielding metal is connected to one of the first initialization signal line and the second initialization signal line.

11. The display panel according to claim 10, wherein the first shielding metal is connected to the second initialization signal line, and the second shielding metal is connected to the first initialization signal line.

12. The display panel according to claim 10, further comprising:
a substrate; and
a pixel driving circuit layer comprising a plurality of the pixel driving circuits;
wherein the pixel driving circuit comprises a semiconductor layer, a first metal layer, a second metal layer, and a third metal layer sequentially disposed on the substrate; the display panel further comprises a first interlayer dielectric layer, a second interlayer dielectric layer, and an interlayer insulating layer, the first interlayer dielectric layer is disposed between the semiconductor layer and the first metal layer, the second interlayer dielectric layer is disposed between the first metal layer and the second metal layer, and the interlayer insulating layer is disposed between the second metal layer and the third metal layer; the semiconductor layer comprises the first active pattern and the second active pattern, the first metal layer comprises the first gate, the second gate, the third gate and the fourth gate, and the shielding metal is disposed on at least one of the second metal layer and the third metal layer.

13. The display panel according to claim 12, further comprising a first via hole extending through the interlayer insulating layer, wherein the second metal layer comprises a first portion of the second initialization signal line and the first shielding metal, and the third metal layer comprises a second portion of the second initialization signal line; and
wherein the first shielding metal is connected to the second portion of the second initialization signal line through the first via hole, and the second portion of the second initialization signal line is connected to the first portion of the second initialization signal line through the first via hole.

14. The display panel according to claim 13, further comprising a second via hole extending through the first interlayer dielectric layer, the second interlayer dielectric layer, and the interlayer insulating layer, wherein the second portion of the second initialization signal line is connected to the second active pattern through the second via hole.

15. The display panel according to claim 12, further comprising a third via hole extending through the interlayer insulating layer, wherein the second metal layer comprises the second shielding metal, and the third metal layer comprises the first initialization signal line; and
wherein the first initialization signal line is connected to the second shielding metal through the third via hole.

16. The display panel according to claim 12, further comprising a fourth via hole extending through the interlayer insulating layer, wherein the second metal layer comprises a first portion of the second initialization signal line, and the third metal layer comprises a second portion of the second initialization signal line and the first shielding metal; and
wherein the first shielding metal is connected to the second portion of the second initialization signal line, and the second portion of the second initialization signal line is connected to the first portion of the second initialization signal line through the fourth via hole.

17. The display panel according to claim 12, wherein the third metal layer is formed with a source and a drain.

18. The display panel according to claim 1, wherein the pixel driving circuit further comprises a storage capacitor, one end of the storage capacitor is connected to a power high potential signal line, and another end of the storage capacitor is connected to the first node.

19. The display panel according to claim 1, wherein the first initialization transistor is a low temperature polysilicon thin film transistor, the compensation transistor is the 1 low temperature polysilicon thin film transistor, there is a gap between projections of the first gate and the second gate on the first active pattern, and there is a gap between projections of the third gate and the fourth gate on the second active pattern.

20. The display panel according to claim 1, wherein two of the pixel driving circuits which are adjacent to each other are arranged laterally and symmetrically, the first initialization transistors in two of the pixel driving circuits which are adjacent to each other are connected to a same initialization signal line, the compensation transistors in two of the pixel driving circuits which are adjacent to each other are connected to a same scan line.
